(19) United States
(12) Patent Application Publication
(10) Pub. No.: US 2017/0111999 A1
(43) Pub. Date: Apr. 20, 2017

(54) METHOD OF FABRICATING CAVITY PRINTED CIRCUIT BOARD

(71) Applicant: DAEDUCK ELECTRONICS CO., LTD., Gyeonggi-do (KR)

(72) Inventors: Jun-Tae AHN, Gyeonggi-do (KR); Seong-Su CHO, Gyeonggi-do (KR)

(21) Appl. No.: 15/172,454

(22) Filed: Jun. 3, 2016

(30) Foreign Application Priority Data
Oct. 14, 2015 (KR) 10-2015-0143174

(51) Int. Cl. H05K 3/46; H05K 1/09; H05K 3/18; H05K 3/00; H05K 3/40

(52) U.S. Cl. CPC H05K 3/4697; H05K 3/4644; H05K 3/002; H05K 3/4076; H05K 3/18; H05K 1/09; H05K 2203/068

(57) ABSTRACT

This invention discloses a fabricating method of the Printed Circuit Board, comprising the steps of (a) laminating an RCF and a copper layer on the internal core via vacuum press; (b) performing a first curing process; (c) making via-holes and filling out the via-holes and coating the surface of the copper layer with copper plating; (d) preparing a mask layer having a window which exposes the surface of the RCF region for the definition of the cavity; (e) etching the RCF with the surface exposed either via the pumice process or via the wet blast process; and (f) removing the mask layer and performing a second curing process.

### CROSS REFERENCE TO RELATED APPLICATION

This application claims priority under 35 USC §119 to Korean Patent Application No. 10-2015-0143174, filed on Oct. 14, 2015, the contents of which are incorporated herein by reference in their entirety. The list of the prior art is the following: Korean Patent Publication No. 10-2015-0107348, Korean Patent Publication No. 10-2013-0032529, PCT Publication WO 2011/099820 A2, US Patent Publication 2008/0117608 A1.

### FIELD OF THE INVENTION

The present invention relates to a Cavity Printed Circuit Board (PCB) and more particularly a fabricating method of a cavity printed circuit board utilizing an RCF (Resin Coated Film).

### BACKGROUND OF THE INVENTION

Recently, PCB industry has been making a great deal of efforts on making the thickness of the PCB thinner and thinner by embedding the chip inside the cavity instead of relying on the conventional surface mounting technology (SMT) which causes the inevitable protrusion from the surface of the PCB.

One of the traditional methods for making a cavity is the laser drill process which removes the epoxy resin by the laser ablation. The laser drill process, however, is not cost-effective in case of a large-size cavity because the duration of laser ablation process tends to be lengthened in proportion to the size of the cavity. In addition, there is a depth limitation of the cavity in case of the laser ablation. The most critical problem of the laser drill process is that a protection layer such as a copper layer is needed on the bottom of the cavity area in order that the bottom layer should not be damaged during the laser ablation. Since a protection layer is needed at the bottom of the cavity, the bottom layer cannot be utilized as a circuit element but a dummy. In other words, the area of the protection layer is just a dummy for the laser ablation and useless from the circuit point of view.

Another prior art for fabricating a cavity is the fill-cut technology which includes the coating of the release film, the laser cutting process, and removal of the release film. However, this fill-cut process requires the accuracy in the position alignment of the release film to the surface of the PCB. In addition, this fill-cut process requires a repetition of automatic or manual alignment and there is a technical limitation for the applicable thickness of the release film. Furthermore, we cannot rule out the possibility of the mismatch during the stacking process. We also cannot rule out the possibility of having the damage at the end of the bottom of the cavity during the laser drilling process.

### SUMMARY OF THE INVENTION

Accordingly, the goal of the present invention is to provide a method of fabricating a cavity for the fine-pitch printed circuit board (PCB).

Another goal of the present invention is to provide a method of fabricating a cavity without causing any damage on the circuit of the internal core.

In order to accomplish the goals of the present invention, an insulating material of the SR (Solder Resist) type such as an RCF (Resin Coated Film) is stacked and coated on the surface of the internal core. The cavity is fabricated by etching the insulating material of the SR (Solder Resist) type either through the pumice process or through the wet blast process.

The present invention has a feature in that an insulating material of the roll type such as RCF (Resin Coated Film) is coated on the surface of the internal core through the vacuum press. In this case, it is recommended that a copper layer of the sheet type is coated on the surface of the insulating material of the roll type for the purpose of having an external circuit. This invention enables us to have an insulating layer of the SR type by curing the RCF and the copper in the baking oven.

Thereafter, the external circuitry is realized by making the via-holes and electroplating the copper, followed by selective etch for the external circuitry. Then we prepare a masking layer by covering the external circuit with the dry film and continue the conventional imaging steps in order to define the cavity area.

The exposed surface of the RCF through the mask window is etched away via the pumice or the wet blast process, which defines a cavity area. Thereafter, we remove the mask and cure the RCF, which is the second curing process. Finally, the solder resist is printed for the protection of the external circuit and the surface of the copper layer is treated via gold plating or by OSP (organic solderability preservative) process.

The pumice process of the present invention shortens the processing time which reduces the cost of the fabrication of the cavity. The present invention resolves the problem of damages on the surface of the circuit during laser drill ablation, which makes it possible to utilize the bottom of the cavity as a circuit instead of utilizing the bottom layer as a protection layer. This enhances the design freedom for the lay out of the PCB circuits.

### BRIEF DESCRIPTION OF THE DRAWINGS

FIGS. 1a through to 1h are figures illustrating the fabrication process sequences in accordance with a preferred embodiment of the present invention.

### DETAILED DESCRIPTION OF THE INVENTION

This invention discloses a fabricating method of the Printed Circuit Board, comprising the steps of (a) laminating an RCF and a copper layer on the internal core via vacuum press; (b) performing a first curing process; (c) making via-holes and filling out the via-holes and coating the surface of the copper layer with copper plating; (d) preparing a mask layer having a window which exposes the surface of the RCF region for the definition of the cavity; (e) etching the RCF with the surface exposed either via the pumice process or via the wet blast process; and (f) removing the mask layer and performing a second curing process.

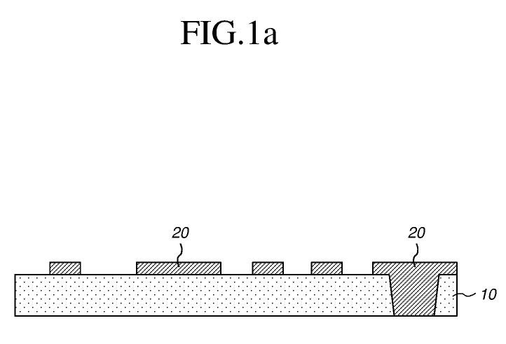

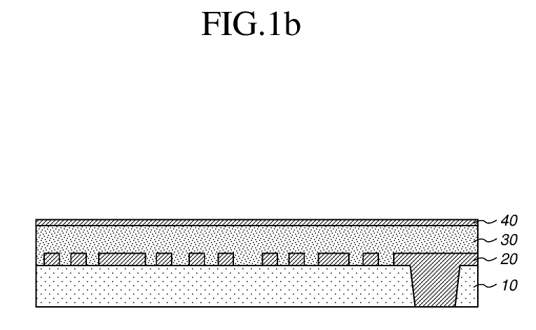

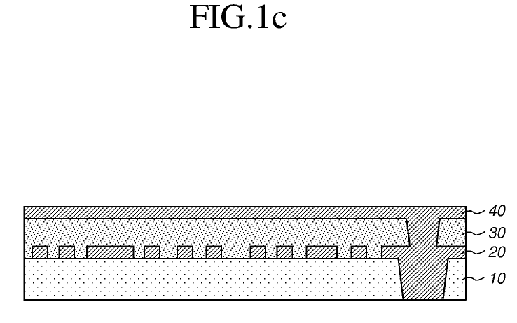

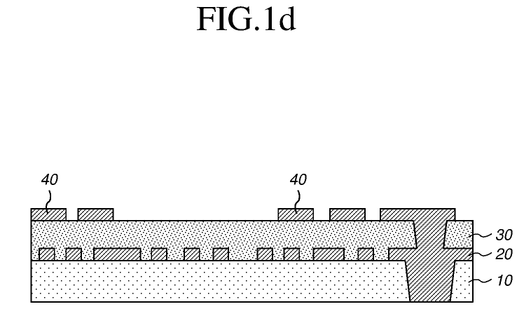

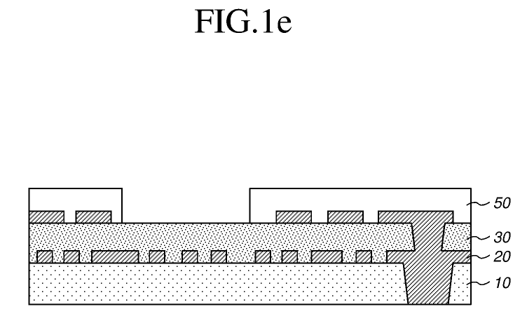

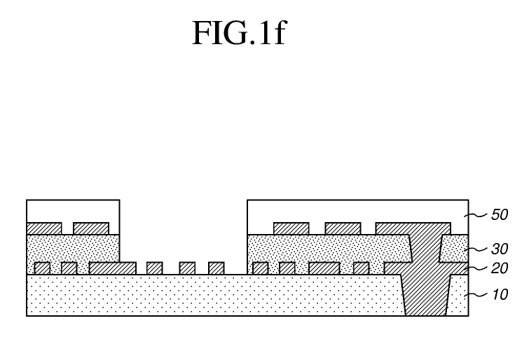

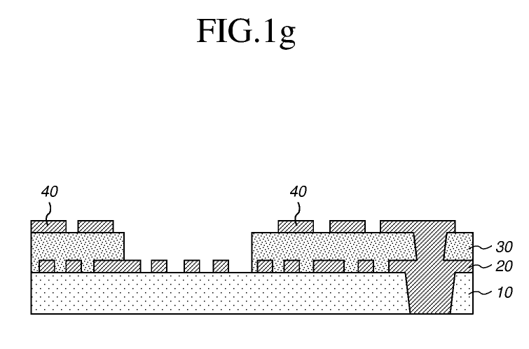

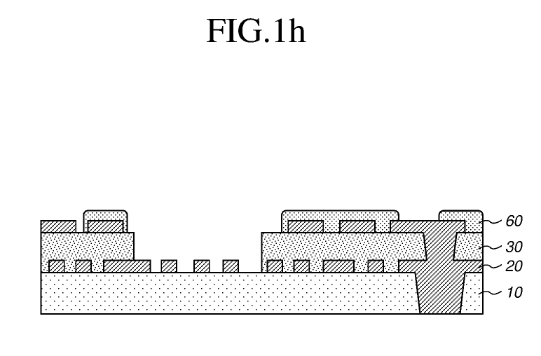

Detailed descriptions will be made on preferred embodiments and constitutional features of the fabricating method in accordance with the present invention with reference to attached figures from FIGS. 1a to FIGS. 1h.

FIGS. 1a through to 1h are drawings depicting the fabrication process in accordance with a preferred embodiment of the present invention.

Firstly, we prepare a circuit on the surface of the internal core. Here, the internal core means the stack of the insulating layer and the conducting layer with circuit pattern. Referring to FIG. 1a, we can see a copper layer 20 having a circuit pattern on the surface of the insulating layer 10.

Referring to FIG. 1b, the present invention has a feature in that an RCF is laminated on the surface of the internal core which has a circuit pattern. This invention has a feature of utilizing the RCF of the roll type instead of utilizing the conventional material such as RCC of the sheet type, PREPREG, and resin of the prior art.

As a preferred embodiment of the present invention, the RCF 30 of the roll type can be laminated on the surface of the internal core by vacuum press and thereon the copper layer 40 of the sheet type can be laminated. The RCF in accordance with the present invention is an insulating layer of the SR type. After the lamination, the pre-cure process is performed by utilizing the baking device. In the following description, this pre-cure process will be called a first curing process.

Referring FIG. 1c, we can make via-holes according to the circuit pattern by the laser drilling the external copper layer 40, followed by copper plating for filling out the via-holes. In FIG. 1c, we used the same drawing number 40 for depicting the laminated copper in FIG. 1b and the electroplated copper.

Referring FIG. 1d, we can make the external circuit by selectively etching the electroplated copper layer 40 in accordance with the pre-determined circuit pattern. Thereafter, a mask layer is formed by selectively etching the dry film in such a way that only the surface of the underneath layer is expose to the air through the window.

Referring to FIG. 1e, a dry film 50 is coated on the RCF 30 in such a way that only the cavity area is exposed through the mask window. Referring to FIG. 1f, the exposed surface of the RCF 30 is etched away either through the pumice process (stone powder blasting process) or through the wet blast process with pattern-transferred dry film as a mask.

Referring to FIG. 1g, we remove the dry film 50 which was used as a mask and then continue a second curing process, which is so-called post cure. Referring to FIG. 1h, solder resist 60 can be printed for the protection of the surface and the exposed copper layer can be finished through gold electroplating or OSP process. Finally, a chip is mounted in the cavity and an appropriate interconnection such as wire bonding or flip-chip bonding is processed.

The aforementioned somewhat widely improves the characteristics and technical advantages of the present invention so that the scope of the invention to be described later can be more clearly understood. The additional characteristics and technical advantages that constitute the scope of the present invention will be described below. The features that the disclosed concept and specific embodiments of the present invention can be instantly used as a basis designing or correcting other structure for accomplishing a similar object with the present invention should be recognized by those skilled in the art.

Further, it will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A fabricating method of the Printed Circuit Board, comprising the steps of:
(a) laminating an RCF and a copper layer on the internal core via vacuum press;
(b) performing a first curing process;
(c) making via-holes and filling out the via-holes and coating the surface of the copper layer with copper plating;
(d) preparing a mask layer having a window which exposes the surface of the RCF region for the definition of the cavity;
(e) etching the RCF with the surface exposed either via the pumice process or via the wet blast process; and
(f) removing the mask layer and performing a second curing process.
